(19) United States
(12) Patent Application Publication
(10) Pub. No.: US 2012/0192938 A1
(43) Pub. Date: Aug. 2, 2012

(54) Method and apparatus involving high-efficiency photovoltaic with p-type oxidant

(76) Inventors: Yasser R. Shaban, Sofia (BG); Milen K. Panteleev, Concord, CA (US)

(21) Appl. No.: 13/018,484

(22) Filed: Feb. 1, 2011

(51) Int. Cl. H01L 31/0216; H01L 31/18

(52) U.S. Cl. 136/256; 438/57; 257/E31.001

(57) ABSTRACT

The present invention is a method and technique (apparatus) to improve the efficiency of the chemical and physical types of photovoltaics. All types of photovoltaics suffer from the build-up of counter-electrons, termed p-type electrons. The p-type electrons induce a potential break to the main potential of the photovoltaic, i.e. causing a reduction to the converted power. The application of the oxidant layer to the p-type semiconductor of the photovoltaic should reduce the p-type electrons from moving in the external circuit, therefore increases the overall efficiency.

### CROSS-REFERENCE TO RELATED APPLICATIONS

Not applicable

### STATEMENT REGARDING FEDERALLY SPONSORED RESEARCH OR DEVELOPMENT

Individual Efforts

### BACKGROUND

Prior and current methods, techniques, and apparatus to generate high efficient solar cells involving:

A) Surface structuring: construction of the cell surface in a pyramid structure, so that incoming light hits the surface several times. For example, U.S. Pat. No. 6,451,218 issued to Holdermann K. on September 2002.
B) Tandem or stacked cells: for example, multijunction cell which is based on utilizing a wide spectrum of radiation, different semiconductor materials, which are suited for different spectral ranges, are arranged one on top of the other. For example, U.S. Pat. No. 6,660,928 issued to Patton Martin O et al. on December 2003 and U.S. Pat. No. 6,147,296 issued to Freundlich Alexandre on November 2000.
C) Concentrator cells: A higher light intensity will be focused on the solar cells by the use of mirror and lens systems. For example U.S. Pat. No. 7,872,192 issued to Fraas et al. on January 2011 and U.S. Pat. No. 4,069,812 issued to M. J. O'Neill on January 1978.

The present invention frames the main cause of the inefficiency of the photovoltaics and courses a new method-and-apparatus of improving its efficiency. The inefficiency of the solar cells is caused by the presence of the counter-electrons, termed p-type electrons, which induces a potential break of the photovoltaic i.e. a reduction of the converted power. The photoelectrons are released from the p-type and n-type semiconductor materials depending on the binding energy of the electrons of the applied material and the quantum energy of the incident photon.

According to electrochemistry, the application of the oxidant layer to the p-type semiconductor of the photovoltaic should reduct the p-type electrons from moving in the external circuit, therefore increases the overall efficiency.

### BRIEF DESCRIPTION OF THE DRAWINGS

Figures included in this invention are briefly described as follows.

FIG. 1 Illustration of the main components involved in the structure of the chemical photovoltaic. It is also the earlier version of the photovoltaic before the mid of sixtieth.

FIG. 2 Illustration of the main components involved in the structure of the physical photovoltaic.

FIG. 3 The vision of the reduction-diagram; it precisely leads to the selection of the p-type oxidant on the basis of electrochemistry. Only three elements are shown here; hydrogen at the center, fluorine at the right and lithium at the left. The direction of the p-type oxidant is ahead of the p-type semiconductor.

FIG. 4 The orientation of the electric field, the p-type oxidant, and the direction of the electric current.

FIG. 5 The course or the importance of the p-type oxidant to the chemical photovoltaic.

FIG. 6 The course or the importance of the p-type oxidant to the physical photovoltaic.

### SUMMARY OF THE INVENTION

The embodiment of the present invention introduces a unique technique and apparatus for the objective of improving the overall efficiency of the photovoltaics (solar cells). Such method and apparatus (denoted 12 in the diagrams) is implemented by placing a material of higher electrode potential, oxidant, than the electrode potential of the p-type semiconductor (11) or p-type electrode (3) according to the electrochemistry.

For the physical photovoltaic, the oxidant material (12) is implanted to the structure, or doped to the structure, or mechanically oriented to the structure, in all cases its position is always next to the p-type semiconductor (11). The reason of applying the oxidant material (12) to the solar cell is to stop the generation of the p-type electrons (5) which establishes a counter-flow of electrons (denoted 6 in the diagrams) emitted by the p-type semiconductor (11).

For the chemical photovoltaic, the oxidant material (12) is placed next to the p-type electrode (3) in order to stop the generation of the p-type electrons (5) which establishes a counter-flow of electrons (6) emitted by the p-type electrode (3).

The normal direction of the electrons, n-type electrons, is denoted 7 in the diagrams, whereas the normal path of the electric current (8) is always in the opposite direction.

### DETAILED DESCRIPTION OF THE INVENTION

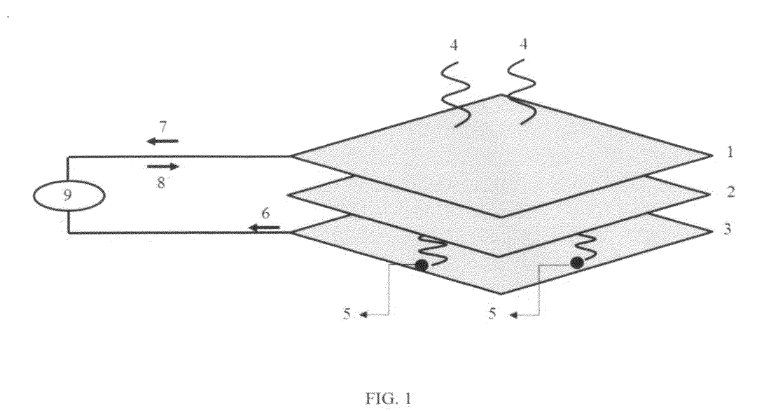

The chemical setup of photovoltaics is illustrated in FIG. 1. As shown in FIG. 1, three main layers characterize the operation of photovoltaic; n-type electrode (1), semiconductor (2), and p-type electrode (3). The emission of the p-type electrons (5) is released as a result of photoelectric effect when light (4) hits the photovoltaic. Such electrons have greater tendency to move (6) in the external circuit when load (9) is present and opposes the direction of the n-type electrons (7) which is the principal photoelectric emitter.

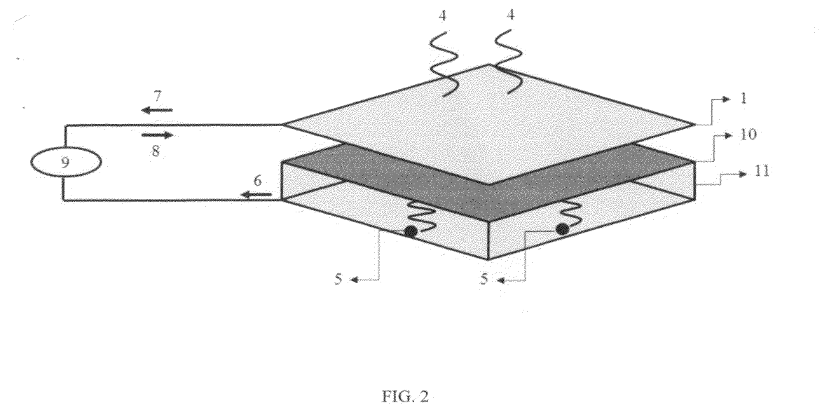

In the physical setup (FIG. 2), three main layers characterize the operation of photovoltaic; n-type electrode (1), p-n junction semiconductor (10), and p-type semiconductor (11). Similar to the chemical setup, the p-type electrons are released due to photoelectric effect and oppose the direction of the n-type electrons.

In both types of photovoltaics, the direction of electric current (8) is always in the opposite direction of the n-type electrons (7) and this is the standard and normal behavior.

When light (4) hits the photovoltaic, a fraction of light is absorbed at the front layer, a fraction is transmitted, a fraction is absorbed in the second layer, and so on. The Einstein's equation of photoelectric effect is given by:

h ν=φ+Eₑ.

Where h is the Planck's constant, ν is the photon's frequency, φ is the binding energy (the least energy needed for electrons to be liberated from the surface), and Eₑ is the residual energy of the emitted electrons. For photoelectric effect h ν must be greater than φ. As a result, the emitted electrons would have energy to move in the direction in which the conductivity is the highest—the external circuit.

The potential and the density of p-type electrons depend on the binding energy of the p-type electrode, the concentration of the p-type atoms, and the fraction of the transmitted photons. These combined factors contribute to the establishment of the counter electrons (6) and reduce the overall efficiency of the photovoltaic since they move in the external circuit and oppose the direction of the n-type electrons. In order to eliminate the negative effect of the p-type electrons we introduce an electron absorber, oxidant, next to the p-type electrode. The introduction of the oxidant material to the photovoltaics can be made chemically (such as solar gel) or physically (such as ion implantation and physical vapor deposition).

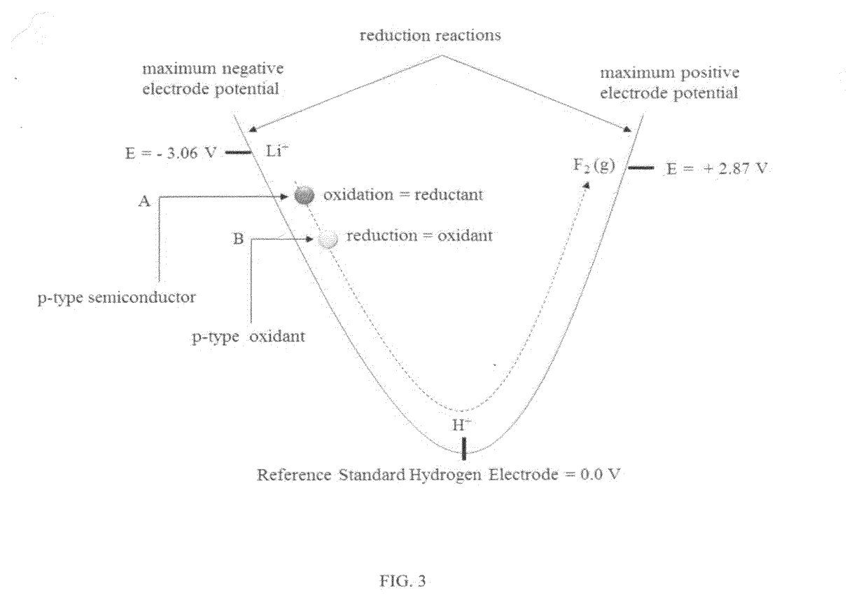

According to electrochemistry, FIG. 3, the choice of the oxidant (12) depends on the choice of the p-type electrode (3) or the p-type semiconductor (11); the types of the dopants and not the semiconductor. (For example, the p-type semiconductor of the silicon wafer photovoltaic is boron).

The choice of the oxidant (denoted B in the diagram) is fluorine-ward (toward fluorine) and in any case the p-type electrode or p-type semiconductor can be any element or substance behind (denoted A in the diagram). The electrochemical reactions of the combinations A and B are as following:

Photons+A→electron or electrons (oxidation),
Here A is ionized positively but there is no charge separation since B is neutralized.
B+electron or electrons→(reduction).

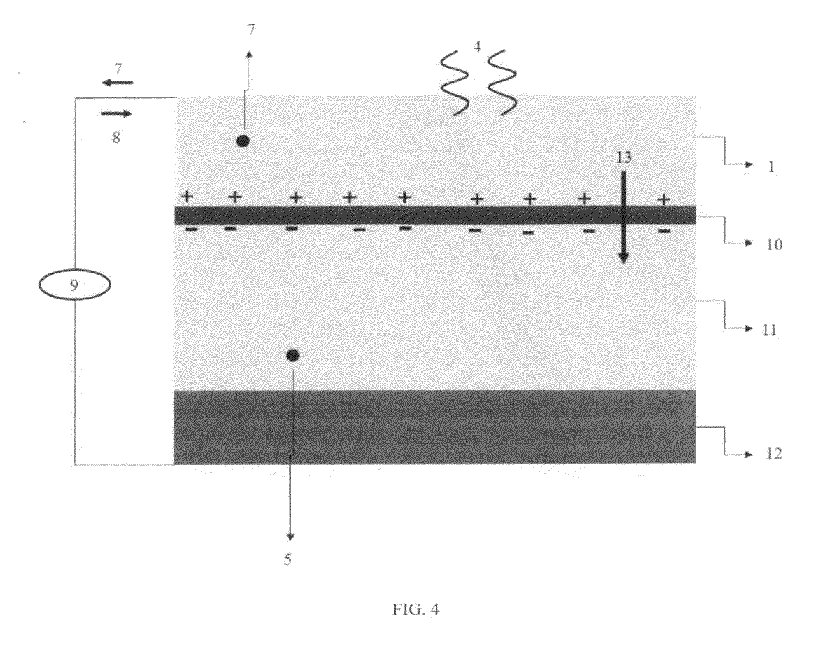

The role of the p-type oxidant not only favors the reduction of the counter electrons (6) but also favors the overall mechanism of the photovoltaic. As shown in FIG. 4, the region of charge separation (10) occurs only in the p-n junction such that the positive charges are drifted toward the n-type (1), whereas the negative charges are drifted toward the p-type (11).

The migration of electrons in the p-n junction is controlled by the concentration of electrons which must be from the high concentration (n-type) to the low concentration (p-type). On the other hand, the migration of positive carriers is from p-type to n-type. Hence a charge separation takes place. The generation of the electric field E (13) is shown from n-type to p-type which is in the same direction of the electric current, clockwise in the diagram.

At the p-n junction, an interior electric field (13) is built up which leads to the separation of the charge carriers that are released by light. Through metal contacts, an electric charge can be tapped. If the outer circuit is closed (9), meaning a consumer is connected a direct current flows.

The role of the p-type oxidant hence accelerate the flow of electric current in the internal circuit by eliminating the generations of the p-type electrons.

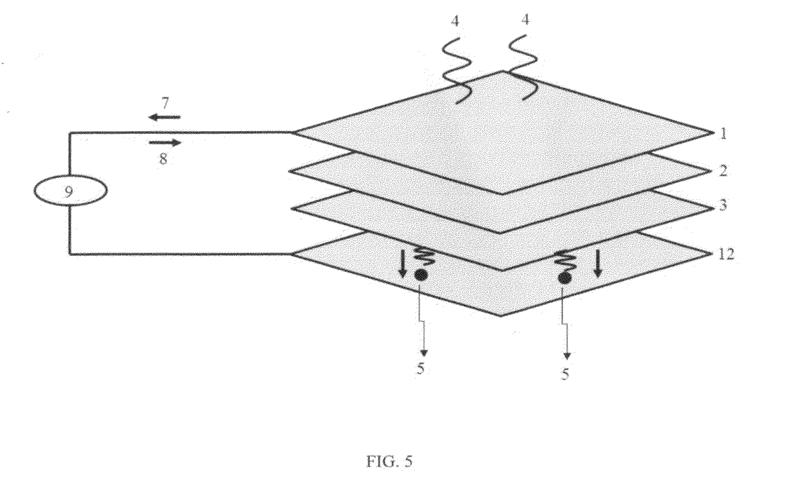

The course of the p-type oxidant (12) in the chemical setup of photovoltaic is shown in FIG. 5.

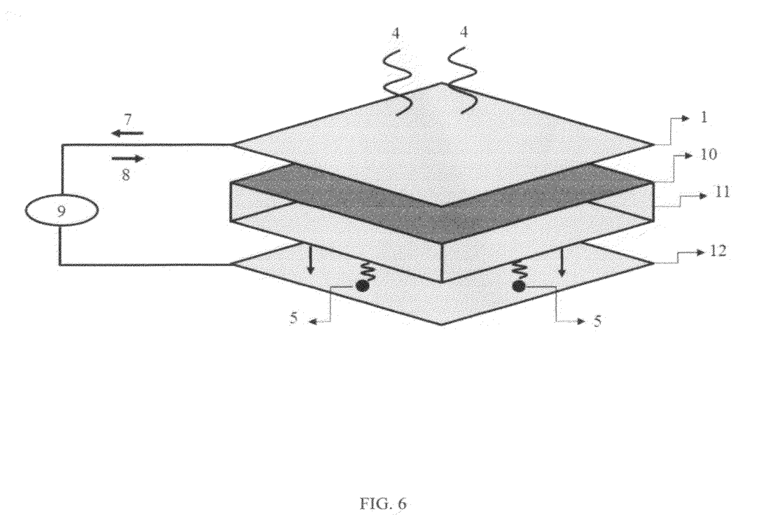

The course of the p-type oxidant (12) in the physical setup of photovoltaic is shown in FIG. 6.

The invention is the p-type oxidant which must be chosen on the basis of electrochemistry and based on the electrode potential of the p-type semiconductor or p-type material in general.

What is claimed is:

1. A method of stopping the emission of p-type electrons in the chemical and physical structures photovoltaics.

2. An apparatus of stopping the emission of p-type electrons in the chemical and physical structures photovoltaics.

3. Any choice of p-type oxidant: element or substance, for claims 1 and 2.
